(19) United States
(12) Patent Application Publication
(10) Pub. No.: US 2022/0319963 A1
(43) Pub. Date: Oct. 6, 2022

(54) SEMICONDUCTOR DEVICE PACKAGE WITH CONDUCTIVE VIAS AND METHOD OF MANUFACTURING

(71) Applicant: STMICROELECTRONICS PTE LTD, Singapore (SG)

(72) Inventor: Jing-En LUAN, Singapore (SG)

(73) Assignee: STMICROELECTRONICS PTE LTD, Singapore (SG)

(21) Appl. No.: 17/700,259

(22) Filed: Mar. 21, 2022

Related U.S. Application Data
(60) Provisional application No. 63/168,914, filed on Mar. 31, 2021.

(51) Int. Cl. H01L 23/495; H01L 23/31; H01L 23/00; H01L 21/56

(52) U.S. Cl. CPC H01L 23/49548; H01L 23/3107; H01L 23/49513; H01L 24/50; H01L 24/48; H01L 21/56; H01L 24/86; H01L 24/85; H01L 2224/48177

(57) ABSTRACT

The present disclosure is directed to embodiments of semiconductor device packages including a plurality of conductive vias and traces formed by an laser-direct structuring process, which includes at least a lasering step and a plating step. First ones of the plurality of conductive vias extend into an encapsulant to contact pads of a die encased within the encapsulant, and second ones of the plurality of conductive vias extend in the encapsulant to end portions of leads in the encapsulant. The second ones of the plurality of conductive vias may couple the leads to contact pads of the die. In some embodiments, the leads of the semiconductor device packages may extend outward and away from encapsulant. In some other alternative embodiments, the leads of the semiconductor device packages may extend outward and away from the encapsulant and then bend back toward the encapsulant such that an end of the lead overlaps a surface of the encapsulant at which the plurality of conductive vias are present.

### BACKGROUND

### Technical Field

The present disclosure is directed to a package with at least one conductive via coupled to a die and at least one electrical connection coupling the die to a lead.

### Description of the Related Art

Generally, semiconductor device packages, such as chip scale packages or wafer level chip scale packages (WLCSPs), contain semiconductor devices, semiconductor die, or integrated circuit die that are encased in a molding compound, a polymer, an encapsulant, etc. The semiconductor devices may be sensors configured to detect any number of quantities or qualities, or may be controllers utilized to control other various electronic components. For example, such semiconductor device packages may detect light, temperature, sound, pressure, stress, strain or any other quantities or qualities. Other semiconductor devices may be controllers, microprocessors, or memory.

A conventional WLCSP may be formed to include conductive pads to which a solder material is coupled to directly for mounting to an electronic component. Usually, the solder material is in the form of solder balls that all have substantially the same shape and size as each other such that the WLCSP may be level when mounted or coupled to a printed circuit board (PCB), a surface of an electronic device, or some other electronic component. For example, a redistribution layer may be formed on a surface of a die and a plurality of conductive pads are formed in the redistribution layer and are exposed such that the solder balls may be coupled to the conductive pads.

When the conventional WLCSP is mounted to a PCB, there is a significant thermal mismatch between a die of the conventional WLCSP and the PCB to which it is mounted. Usually, the die has a coefficient of thermal expansion (CTE) that is less than a CTE of the PCB. This difference in the CTEs results in the die and the PCB expanding and contracting by different amounts when exposed to changes in temperature (e.g., from cold to hot, or hot to cold). The solder balls are exposed to these differences in expansion and contraction and may lead to failure in the solder balls such as cracking, shearing, breaking, delamination, or some other similar failure occurring within the solder balls. These failures may result in malfunction of the conventional WLCSP, which may ultimately lead to failure of an electronic device's functionality in which the conventional WLCSP is present or utilized.

When solder balls are formed on conductive pads of the conventional WLCSP to be mounted to the PCB, the conductive pads must be spaced apart by a relatively large distance to avoid cross-talk between the solder balls that are adjacent to each other. For example, if during a reflow process to mount the WLCSP to the PCB utilizing the solder balls, the solder balls may come into physical contact with each other or may come close enough with each other to result in arcing causing cross-talk between the adjacent solder balls resulting in the WLCSP not functioning appropriately or as expected. This inappropriate functioning may significantly reduce the usability of an electronic device as a whole, which may be a phone, a smart phone, a tablet, a television, a computer, a laptop, a camera, or some other electronic device in which the semiconductor package is present within.

This spacing of the solder balls and the thermal mismatch limits the number of input/output (I/O) contacts that may be included in the WLCSP, which limits the WLCSP's ability to perform every increasingly complex functions.

### BRIEF SUMMARY

The present disclosure is directed to embodiments of semiconductor device packages as well as methods of manufacturing the embodiments of the semiconductor devices packages. These embodiments have a combination of electrical connections that provide the package with a board level reliability (BLR) and robustness capable of withstanding stresses and strains caused by Thermal Cycling On Board (TCoB), and have multiple input/output (I/O) electrical connections.

In at least one embodiment of a semiconductor device package, the semiconductor device package includes a die, a die pad, and an adhesive coupling the die to the die pad. The die includes a plurality of contact pads. The package further includes an encapsulant that encases the die, the die pad, and the adhesive. At least one conductive via extends into the package to one of the contact pads and provides electrical signals to be sent to and from the die within the encapsulant. At least one lead extends into the package and is coupled to one of the contact pads through a second conductive via. The second conductive via extends into and across the encapsulant to couple the lead to the contact pad.

In at least one embodiment of a method of manufacturing of the at least one embodiment of the semiconductor device package, the encapsulant utilized to form the semiconductor device package is doped with an additive material that is activated when exposed to a laser during a laser direct structuring (LDS) process. This laser utilized in this LDS process forms openings in the encapsulant, and, successively, forms first conductive layers lining the openings. Ones of the first conductive layers are formed on a surface of the at least one lead and surfaces of the contact pads. In a conductive plating step after this LDS process is completed, a second conductive layer is formed on the first conductive layers filling the openings, which forms the first and second conductive vias within the encapsulant and the at least one embodiment of the semiconductor device package.

### BRIEF DESCRIPTION OF THE SEVERAL VIEWS OF THE DRAWINGS

For a better understanding of the embodiments, reference will now be made by way of example to the accompanying drawings. In the drawings, identical reference numbers identify the same or similar elements or acts unless the context indicates otherwise. The sizes and relative proportions of the elements in the drawings are not necessarily drawn to scale. For example, some of these elements may be enlarged and positioned to improve drawing legibility.

FIG. 1A illustrates an embodiment of a semiconductor device package of the present disclosure taken along line A-A in FIG. 1B;

FIG. 1B illustrates a bottom plan view of the embodiment of the semiconductor device package as shown in FIG. 1A;

FIG. 1C illustrates a zoomed-in enhanced view of the embodiment of a first conductive via of the embodiment of the semiconductor device package as shown in FIGS. 1A and 1B;

FIG. 2A illustrates an alternative embodiment of a semiconductor device package of the present disclosure taken along line B-B in FIG. 2B;

FIG. 2B illustrates a bottom plan view of the alternative embodiment of the semiconductor device package of as shown in FIG. 2A;

FIG. 3 is a cross-sectional view of an alternative embodiment of a semiconductor device package of the present disclosure;

FIG. 4 is a cross-sectional view of an alternative embodiment of a semiconductor device package of the present disclosure;

FIG. 5 is a cross-sectional view of an alternative embodiment of a semiconductor device package of the present disclosure;

FIG. 6 is a cross-sectional view of an alternative embodiment of a semiconductor device package of the present disclosure;

FIG. 7 is a cross-sectional view of an alternative embodiment of a semiconductor device package of the present disclosure;

FIG. 8 is a cross-sectional view of an alternative embodiment of a semiconductor device package of the present disclosure;

FIG. 9 is a cross-sectional view of the embodiment of the semiconductor package as illustrated in FIGS. 1A and 1B coupled to a substrate;

FIGS. 10A-10C illustrate steps of a method of manufacturing the embodiment of the semiconductor device package as illustrated in FIGS. 1A and 1B;

FIG. 11 illustrates a step of an alternative method of manufacturing the alternative embodiment of the semiconductor device package as illustrated in FIG. 3; and

FIGS. 12A-12C illustrate steps of an alternative method of manufacturing the alternative embodiment of the semiconductor device package as illustrated in FIGS. 2A and 2B.

### DETAILED DESCRIPTION

In the following description, certain specific details are set forth in order to provide a thorough understanding of various embodiments of the disclosure. However, one skilled in the art will understand that the disclosure may be practiced without these specific details. In other instances, well-known structures associated with electronic components, packages, and semiconductor fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second, third, etc., does not necessarily imply a ranked sense of order, but rather may only distinguish between multiple instances of an act or a similar structure or material.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terms “top,” “bottom,” “upper,” “lower,” “left,” and “right,” are used for only discussion purposes based on the orientation of the components in the discussion of the Figures in the present disclosure as follows. These terms are not limiting as the possible positions explicitly disclosed, implicitly disclosed, or inherently disclosed in the present disclosure.

The term “substantially” is used to clarify that there may be slight differences and variation when a package is manufactured in the real world, as nothing can be made perfectly equal or perfectly the same. In other words, “substantially” means and represents that there may be some slight variation in actual practice and instead is made or manufactured within selected tolerances.

As used in this specification and the appended claims, the singular forms “a,” “an,” and “the” include plural referents unless the content clearly dictates otherwise.

While various embodiments are shown and described with respect to semiconductor die and semiconductor packages, it will be readily appreciated that embodiments of the present disclosure are not limited thereto. In various embodiments, the structures, devices, methods and the like described herein may be embodied in or otherwise utilized in any suitable type or form of semiconductor die or packages, and may be manufactured utilizing any suitable semiconductor die and packaging technologies as desired.

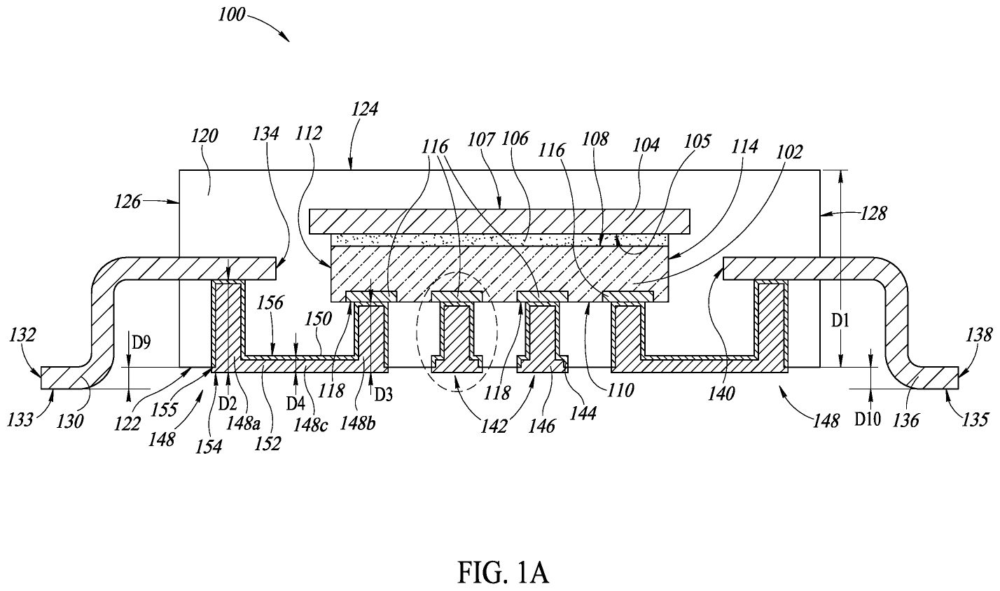

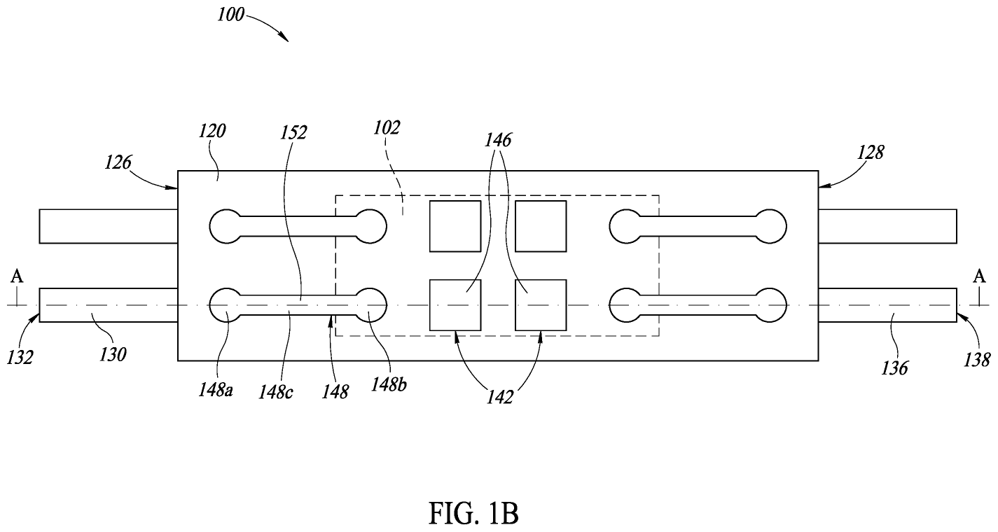

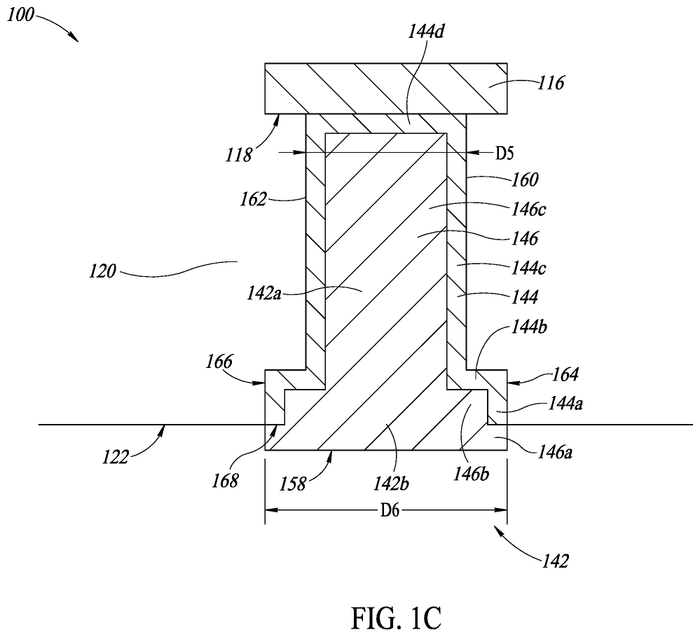

The present disclosure illustrates semiconductor device packages having a combination of electrical connections that provide the packages with a board level reliability (BLR) and robustness capable of withstanding stresses and strains caused by Thermal Cycling On Board (TCoB). The TCoB may be caused by expansion and contraction from the at least one embodiment of the semiconductor device package being moved from a hot environment to a cold environment and vice versa. For example, the semiconductor device package as shown in FIG. 1A includes an encapsulant, an end of a first conductive via at a first surface of the encapsulant, a first lead extending from a first sidewall of the encapsulant, and a second lead extending from a second sidewall of the encapsulant. The second sidewall of the encapsulant is opposite to the first sidewall of the encapsulant. When the first and second leads and the first conductive via are coupled to a printed circuit board (PCB) by a solder material, the first and second leads may bend and flex in reaction to expansion and contraction in the semiconductor device package caused by a change in temperature. This bending and flexing of the leads absorbs stresses and strains caused by the expansion and contraction reducing the likelihood of cracks or delamination of the solder material or other electrical connections of the semiconductor device package. These electrical connections may be internal electrical connections that are within the encapsulant (e.g., conductive vias, conductive layers, wire bonds, or some other like internal electrical connection) or external electrical connections that are connections outside the encapsulant (e.g., solder balls, wire bonds, leads, contact pads, or some other like external electrical connection). For example, see leads of the semiconductor device package as shown in FIG. 1A.

Similar to the TCoB as discussed directly above, when the semiconductor device package as shown in FIG. 1A is mounted to the PCB, there may be a thermal mismatch between the semiconductor device package and the PCB. For example, the PCB may expand and contract by a first amount and the semiconductor device package may expand and contract by a second amount that is different from the first amount. This difference in expansion and contraction between the PCB and the semiconductor device package may cause the same or similar failures as discussed above. However, the bending and flexing of the leads absorbs stresses and strains caused by difference in expansion and contraction of the PCB and the semiconductor device package reducing the likelihood of cracks or delamination of the solder material or other failures in electrical connections between the PCB and the semiconductor device package.

While having good BLR, robustness against TCoB, and robustness against thermal mismatch as discussed directly above, the semiconductor device package as shown in FIG. 1A has multiple input/output (I/O) electrical connections to receive and send a number of electrical signals. These multiple I/O electrical connections of the semiconductor device package provides the semiconductor device package with the capability to perform ever increasingly complex functions. These multiple I/O electrical connections of the semiconductor device package may include the first and second leads, the contact pad, as well as several more contact pads and leads. These multiple I/O electrical connections keep a footprint (e.g., the amount of overall space taken up by a package within an electrical device) of the at least one embodiment of the semiconductor device package that is relatively small as compared to other conventional semiconductor device packages.

FIG. 1A is a cross-sectional view of an embodiment of a semiconductor device package 100 taken along line A-A as shown in FIG. 1B. The package 100 includes a die 102, a die pad 104, and an adhesive 106 coupling the die 102 to the die pad 104. The adhesive 106 may be a glue, a die attach film (DAF), or some other type or adhesive suitable for coupling the die 102 to a first surface 105 of the die pad 104, which faces towards the die 102. The die pad 104 further includes a second surface 107 opposite to the first surface 105. The adhesive 106 extends from a first surface 108 of the die 102 to the first surface 105 of the die pad 104, and the adhesive 106 is in physical contact with the first surface 105 of the die pad 104 and the first surface 108 of the die 102. The die pad 104 may be a heat sink that absorbs heat output by the die 102. In some embodiments, the adhesive 106 may be a conductive adhesive that electrically coupled the die pad 104 to the die 102.

The die 102 includes the first surface 108, a second surface 110 opposite to the first surface 108, a first sidewall 112 that extends from the first surface 108 to the second surface 110, and a second sidewall 114 opposite to the first sidewall 112. The second sidewall extends from the first surface 108 to the second surface 110. The first and second sidewalls 112, 114 are transverse to the first and the second surfaces 108, 110. The first and second surfaces 108, 110 extend from the first sidewall 112 to the second sidewall 114.

The die 102 further includes a plurality of contact pads 116 at the second surface 110 that are coupled to and in electrical communication with active and passive electrical components (not shown) of the die 102. The plurality of contact pads 116 provide electrical access to the active and passive electrical components within the die 102 such that signals may be communicated to and from the die 102. For example, the contact pads 116 may provide an electrical path for a control signal to be sent to passive and active components within the die 102, and the contact pads 116 may provide an electrical path for a data signal to be sent from the die 102. The control signal may be sent from an external component such as a control unit, a memory, a controller, or some other like electronic device or component. The data signal may be sent to an external component, which may be a memory, a semiconductor device package, a die, or some other like electrical device or component. Each one of the plurality of contact pads 116 includes a contact surface 118. The plurality of contact pads 116 may be a plurality of conductive pads. The second surface 110 may be an active surface of the die 102.

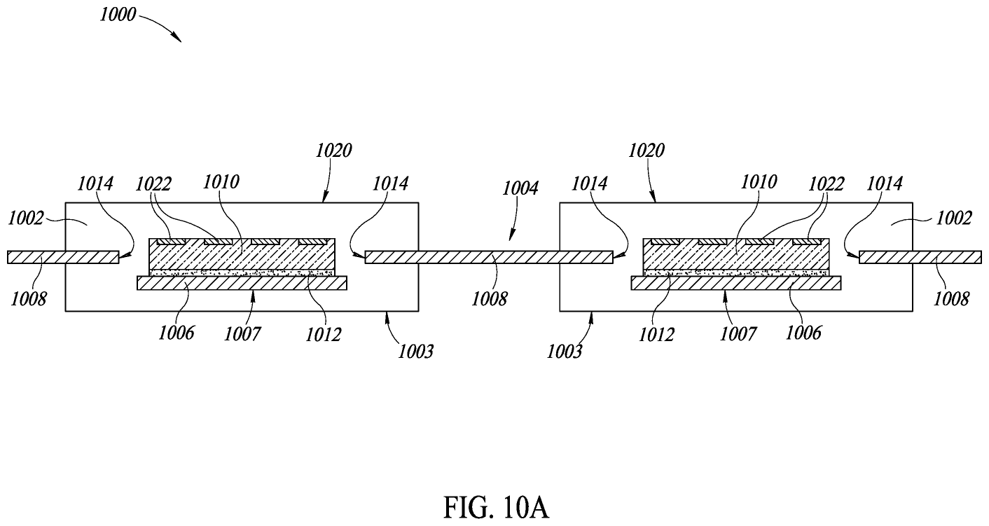

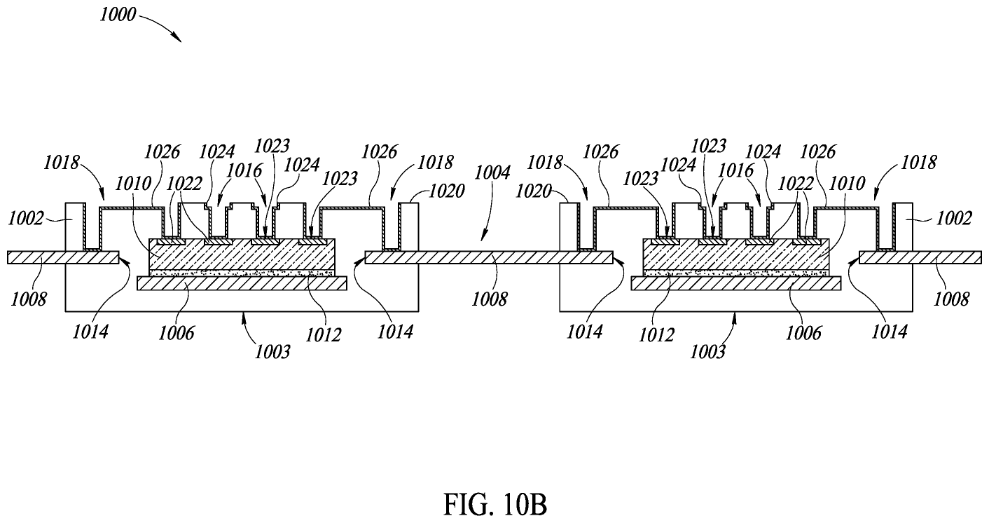

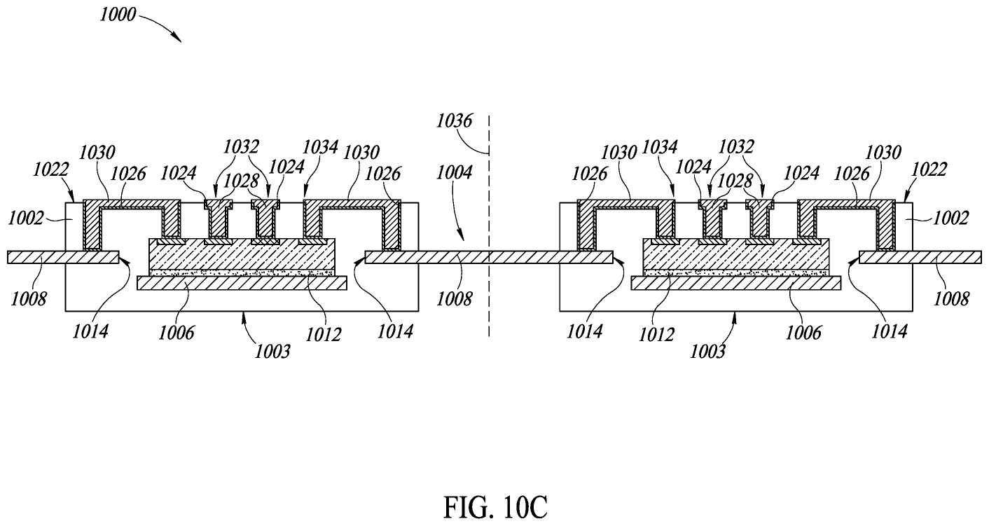

The package 100 further includes an encapsulant 120. For example, the encapsulant 120 may be an epoxy material, a plastic material, an insulating material, a non-conductive material, a molding compound material, or some other like or suitable type of encapsulant material. The encapsulant 120 may be doped with an additive material that becomes electrically conductive when exposed to a laser, the details of which will be described in more detail with respect to FIGS. 10A-10C later within the present disclosure.

The encapsulant 120 encases the die pad 104, the die 102, and the adhesive 106. The encapsulant 120 is on and covers the second surface 107 of the die pad 104, and includes a third surface 122 and a fourth surface 124 opposite to the third surface 122. The third (e.g., lower) surface 122 is at a bottom surface of the package 100 based on the orientation in FIG. 1A, and the fourth (e.g., upper) surface 124 is at a top surface of the package 100 based on the orientation in FIG. 1A. A first dimension D1 extends from the third surface 122 to the fourth surface 124 of the encapsulant 120. For example, the first dimension D1 may range from 350-μm (micrometers) to 1000-μm (micrometers).

The encapsulant 120 further includes a third sidewall 126 extending from the third surface 122 to the fourth surface 124, and a fourth sidewall 128 extending from the third surface 122 to the fourth surface 124. The third and fourth sidewalls 126, 128 are transverse to the third and fourth surfaces 122, 124. The third sidewall 126 is at the left-hand side of the package 100 based on the orientation of FIG. 1A, and the fourth sidewall is at the right-hand side of the package 100 based on the orientation of FIG. 1A.

A first lead 130 of the package 100 extends outward from the third sidewall 126 of the encapsulant 120. The first lead 130 includes a first end 132 outside of the encapsulant 120 and a second end 134 within the encapsulant 120. The second end 134 is laterally adjacent to and spaced apart from the first sidewall 112 of the die 102 based on the orientation of the package 100 as shown in FIG. 1A. The first lead 130 includes a first mounting surface 133 directly adjacent to the first end 132 of the first lead 130.

A second lead 136 of the package 100 extends outward from the fourth sidewall 128 of the encapsulant 120. The second lead 136 includes a third end 138 outside of the encapsulant 120 and a fourth end 140 within the encapsulant 120. The fourth end 140 is laterally adjacent to and spaced apart from the second sidewall 114 of the die 102 based on the orientation of the package 100 as shown in FIG. 1A. The fourth end 140 is separated from the second end 134 by the die 102 within the encapsulant 120. In other words, the die 102 is positioned between the second end 134 of the first lead 130 and the fourth end 140 of the second lead 136. The second lead 136 includes a second mounting surface 135 directly adjacent to the third end 138 of the second lead 136.

Ones of a plurality of first conductive vias 142 extend into the third surface 122 of the encapsulant 120 to respective ones of the plurality of contact pads 116. Each one of the first conductive vias 142 includes a first conductive layer 144 and a second conductive layer 146 on and covering the first conductive layer 144. The first conductive layer 144 is less thick than the second conductive layer 146, which can readily be seen in FIG. 1A. The first conductive layer 144 may be a liner layer, a laser direct structuring (LDS) layer, an LDS mask layer, a seed layer, or some other like or suitable type conductive material. The second conductive layer 146 may be a plating layer, a deposited layer, or some other like or suitable type of conductive material. The second conductive layer 146 is separated from the encapsulant 120 by the first conductive layer 144 upon which the second conductive layer 146 is present. The second conductive layers 146 may not physically contact the encapsulant 120 as the first conductive layers 144 may act as a barrier separating the second conductive layer 146 from the encapsulant 120.

In this embodiment of the package 100, the second conductive layers 146 of the plurality of first conductive vias 142 protrude outward from the third surface 122 of the encapsulant 120. In some other alternative embodiments of the package 100, the second conductive layers 146 may not protrude outward from the encapsulant 120.

The plurality of first conductive vias 142 have a T-shape when viewed in the cross-section of the package 100 as shown in FIG. 1A. The details and dimensionality of the plurality of first conductive vias 142 will be discussed in further detail with respect to FIG. 1C.

A plurality of second conductive vias 148 extend into the encapsulant 120 to ones of the plurality of contact pads 116 and to respective ends 134, 140 of the first and second leads 130, 136. For example, the second conductive via 148 at the left-hand side of the package 100 based on the orientation in FIG. 1A is coupled to the second end 134 of the first lead 130, whereas the second conductive via 148 at the right-hand side of the package 100 based on the orientation in FIG. 1A is coupled to the fourth end 140 of the second lead 136. The plurality of second conductive vias 148 protrude outward from the third surface 122 of the encapsulant 120. In some embodiments, the plurality of the second conductive vias 148 may not protrude outward from the third surface 122 of the encapsulant 120.

Each one of the plurality of second conductive vias 148 includes a third conductive layer 150 and a fourth conductive layer 152 on and covering the third conductive layer 150. The third conductive layer 150 is less thick than the fourth conductive layer 152, which can readily be seen in FIG. 1A. The third conductive layer 150 may be a liner layer, a laser direct structuring (LDS) layer, an LDS mask layer, a seed layer, or some other like or suitable type of conductive material. The fourth conductive layer 152 may be a plating layer, a deposited layer, or some other like or suitable conductive material. The fourth conductive layer 152 is separated from the encapsulant 120 by the third conductive layer 150 upon which the fourth conductive layer 152 is present. The fourth conductive layer 152 may not physically contact the encapsulant 120 as the third conductive layers 150 may act as a barrier separating the fourth conductive layer 152 from the encapsulant 120.

For the sake of simplicity and brevity of the present disclosure, only the details of the second conductive via 148 at the left-hand side of FIG. 1A will be discussed in further detail as follows. However, it will be readily appreciated that this discussion applies in a similar manner to similar features of the second conductive via 148 at the right-hand side of FIG. 1A with respect to the die 102 and the second lead 136.

The second conductive via 148 includes a first portion 148a, a second portion 148b, and a third portion 148c. The first, second, and third portions 148a, 148b, 148c include portions of the third conductive layer 150 and the fourth conductive layer 152. The first, second, and third portions 148a, 148b, 148c are integral each other, and, at least in this embodiment, the first, second, and third portions 148a, 148b, 148c are made of continuous and unitary materials of the third and fourth conductive layers 150, 152. The first, second, and third portions 148a, 148b, 148c of the second conductive via 148 extend into the third surface 122 of the encapsulant 120.

The first portion 148a extends into the third surface 122 of the encapsulant 120 to the first lead 130. The first portion 148a is coupled to the first lead 130. The first portion 148a has a second dimension D2 that extends from the first lead 130 to a surface 154 of the second conductive via 148, which is also a surface of the fourth conductive layer 152. The third and fourth conductive layers 150, 152 are on the first lead 130.

The package 100 includes a dimension D9 extending from the third surface 122 of the encapsulant 120 to the first mounting surface 133 of the first lead 130. The package 100 further includes a dimension D10 extending from the third surface 122 to the mounting surface 135 of the second lead 136. In some embodiments, the mounting surface 133 of the first lead 130 may be substantially coplanar with the third surface 122 of the encapsulant 120.

The second portion 148b extends into the third surface 122 of the encapsulant 120 to the left-most contact pad 116 of the die 102 based on the orientation of FIG. 1A. The second portion has a third dimension D3 that extends from the contact surface 118 of the left-most contact pad 116 to the surface 154. The third dimension D3 is less than the second dimension D2, which can readily be seen in FIG. 1A.

The third portion 148c extends into the third surface 122 of the encapsulant 120 and terminates within the encapsulant 120 before reaching the die 102 or the first lead 130. The third portion 148c extends from the first portion 148a to the second portion 148b and electrically couples the first portion 148a to the second portion 148b. The third portion 148c is transverse to the first portion 148a and the second portion 148b of the second conductive via 148. The third portion 148c may be an electrical trace, an electrical connection, or some other similar or like electrical structure coupling the first portion 148a to the second portion 148b. The third portion has a fourth dimension D4 that extends from a surface 156 of the third conductive layer 150 that is between the first and second portions 148a, 148b. The fourth dimension D4 is less than the second dimension D2 and the third dimension D3.

The second conductive via 148 protrudes from the third surface 122 of the encapsulant 120, and the second conductive via 148 includes the surface 154, which is a surface of the fourth conductive layer 152. In this embodiment, the surface 154 is exposed from the third surface 122 of the encapsulant 120. In some other embodiments, the surface 154 may be substantially coplanar with the third surface 122 of the encapsulant 120. In some embodiments, the surface 154 may be substantially coplanar with the mounting surfaces 133, 135 of the first and second leads 130, 136.

In the some alternative embodiments, when the surface 154 is substantially coplanar with third surface 122 of the encapsulant 120, end surfaces 155 of the third conductive layer 150 may be exposed at the third surface 122 of the encapsulant 120. The end surfaces 155 may be substantially coplanar with the third surface 122 of the encapsulant 120 and the surface 154 of the fourth conductive layer 152.

FIG. 1B illustrates a bottom plan view of the package 100 as shown in FIG. 1A. The package 100 includes additional leads that are not visible in FIG. 1A. In this embodiment, the package 100 has four leads. However, in some other alternative embodiments, the package 100 may have two leads, three leads, five leads, or any other suitable number of leads.

As seen in FIG. 1B, the first conductive vias 142 are positioned in a central region of the package 100. The second conductive vias 148 are laterally spaced apart from the first conductive vias 142. In other words, the second conductive vias 148 are positioned on a right-hand side and a left-hand side of the first conductive vias 142 based on the orientation of the package 100 as shown in FIG. 1B.

FIG. 1C illustrates a zoomed-in enhanced view of the encircled left-most first conductive via 142 as shown in FIG. 1A. For brevity and simplicity of the present disclosure, only details with respect to the left-most first conductive via 142 will be discussed. However, it will be readily appreciated that the following discussion of the left-most first conductive via 142 will apply to the right-most first conductive via 142 as shown in FIG. 1A.

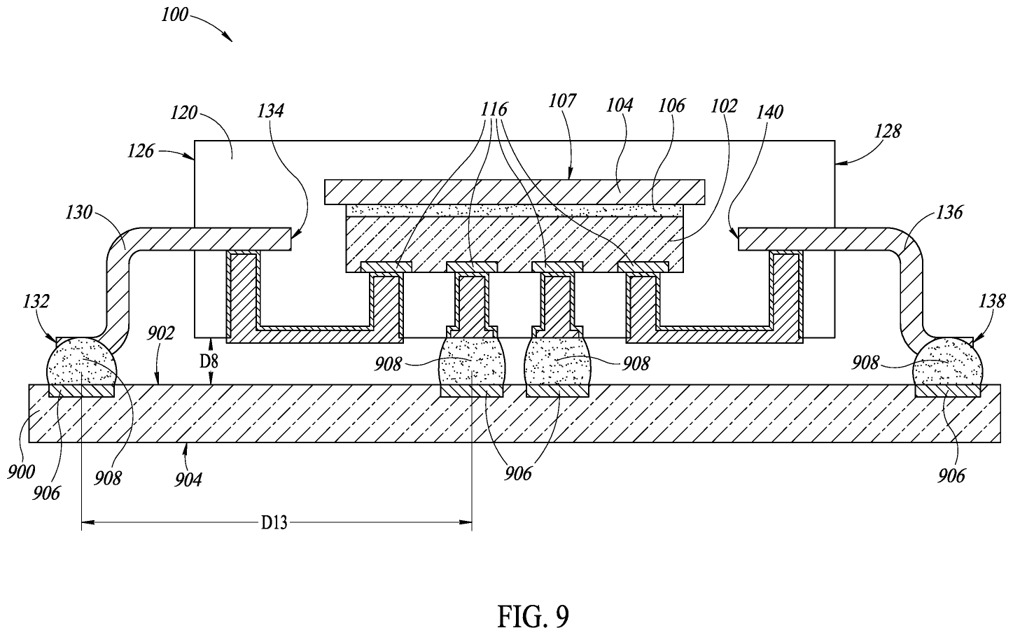

The first conductive via 142 includes an exposed surface 158 that faces away from the die 102. The exposed surface 158 may be a mounting surface to which a solder material is coupled to for mounting or bonding the package 100 to substrate 900 (e.g., a printed circuit board, a semiconductor wafer, or some other similar or like component), which can readily be seen in FIG. 9. As discussed earlier, in this embodiment, the first conductive via 142 protrudes outward from the third surface 122 of the encapsulant 120 such that the exposed surface 158 is spaced outward from the third surface 122. In some alternative embodiments, the exposed surface 158 may be substantially coplanar with the third surface 122 of the encapsulant 120. In the some alternative embodiments, when the exposed surface 158 of the second conductive layer 146 is substantially coplanar with the third surface 122 of the encapsulant, the second conductive layer 146 does not cover an end surface 168 of the first conductive layer 144. The end surface 168 of the first conductive layer 144 may be substantially coplanar with the third surface 122.

A first portion 142a of the first conductive via 142 is adjacent to the contact pad 116 and a second portion 142b of the first conductive via 142 is spaced apart from the contact pad 116 by the first portion 142a. The first portion 142a has a first side 160 and a second side 162 opposite to the first side 160. The first and second sides 160, 162 are transverse to the contact surface 118 of the contact pad 116. The first portion 142a has a fifth dimension D5 extending from the first side 160 to the second side 162. The second portion 142b of has a third side 164 and a fourth side 166 opposite to the third side 164. The third and fourth sides 164, 166 are transverse to the contact surface 118 of the contact pad 116. The second portion 142b has a sixth dimension D6 extending from the third side 164 and the fourth side 166. The sixth dimension D6 is greater than the fifth dimension D5, which can readily be seen in FIG. 1C. The first and second portions 142a, 142b may be cylindrical pillars, rectangular pillars, square pillars, or some other shape or sized pillar that extends into the third surface 122 of the encapsulant 120 to at least one of the contact pads 116. For example, the fifth dimension D5 may range from 15-μm (micrometers) to 80-μm (micrometers) and the sixth dimension D6 may range from 100-μm (micrometers) to 300-μm (micrometers).

The third and fourth sides 164, 166 includes sides of the first conductive layer 144 and the second conductive layer 146. These sides of the first conductive layer 144 and the second conductive layer 146 are substantially coplanar with each other to form the third and fourth sides 164, 166 of the first conductive via 142.

The second conductive layer 146 covers a surface 168 of the first conductive layer 144. In other words, the surface 168 is an end surface of the first conductive layer 144 at which the first conductive layer 144 terminates. The surface 168 of the second conductive layer 146 is substantially coplanar with the third surface 122 of the encapsulant 120. The surface 155 of the third conductive layer 150 is similar to the surface 168 of the second conductive layer 146.

The first conductive layer 144 includes a first portion 144a, a second portion 144b, a third portion 144c, and a fourth portion 144d. The first portion 144a includes the surface 168 and extends into the third surface 122 of the encapsulant 120 to the second portion 144b. The first portion 144a is transverse to the second portion 144b and the second portion 144b extends to the third portion 144c. The second portion 144b is transverse to the third portion 144c, and the third portion 144c extends to the fourth portion 144d. The third portion 144c is transverse to the fourth portion 144d, and the fourth portion 144d is on the contact surface 118 of the contact pad 116. The first portion 144a and the second portion 144b define an L-shape portion adjacent to the third surface 122 of the encapsulant 120.

The second conductive layer 146 includes a fifth portion 146a that is on and covers the surface 168 of the first portion 144a, a sixth portion 146b that is on and covers the second portion 144b, and a seventh portion 146c that is on and covers the third portion 144c and the fourth portion 144d. The fifth portion 146a extends to the sixth portion 146b. The sixth portion 146b extends from the fifth portion 146a to the seventh portion 146c. The seventh portion 146c extends from the sixth portion 146b to the fourth portion 144d of the first conductive layer 144.

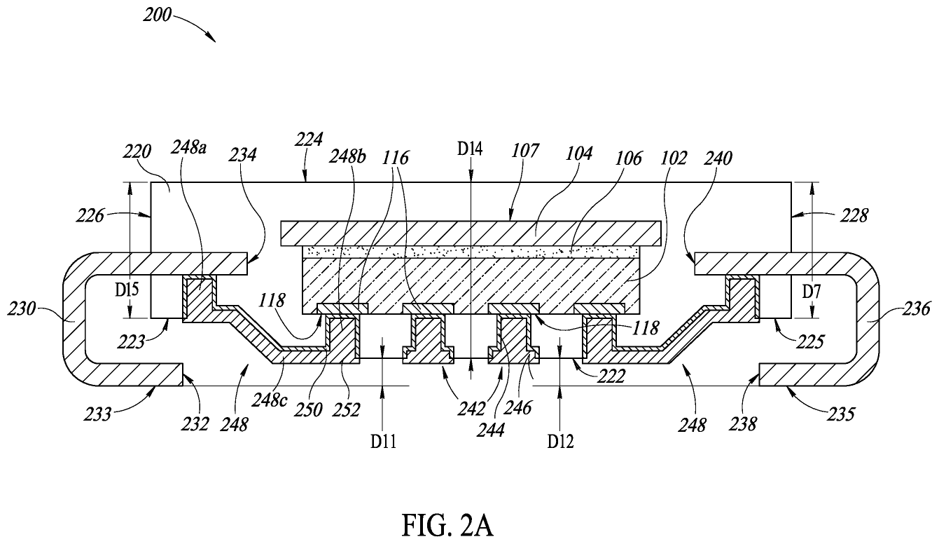

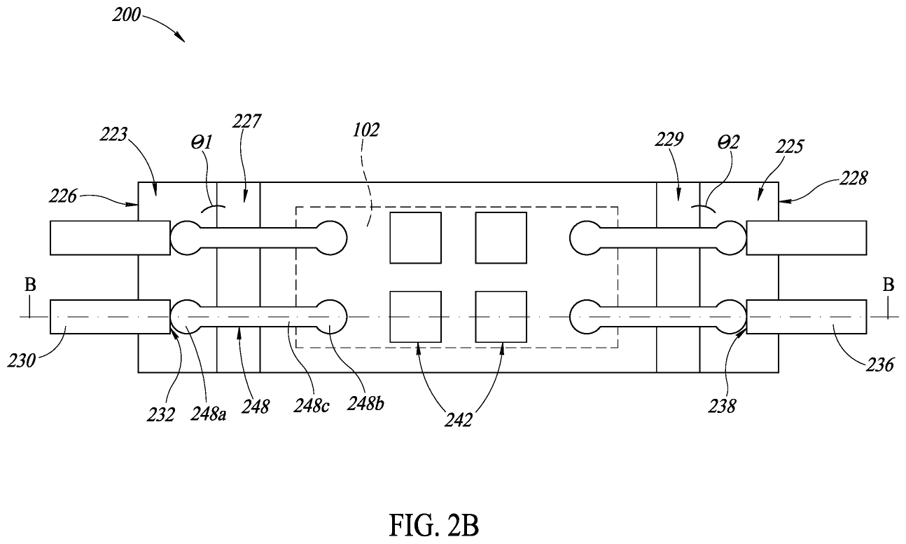

FIG. 2A illustrates a cross-sectional view of an alternative embodiment of a package 200 taken along line B-B in FIG. 2B. FIG. 2B is a bottom plan view of the package 200 as shown in FIG. 2A. For the sake of simplicity and brevity of the present disclosure, only differences or additional features of the package 200 as compared to the package 100 as shown in FIG. 1A-1C will be discussed in further detail herein. The same reference numerals will be utilized to indicate features of the package 200 that are the same or similar to those features as described earlier with respect to the package 100 as shown in FIGS. 1A-1C.

An encapsulant 220 of the package 200 is the same or similar to the encapsulant 120 as discussed earlier with respect to the package 100 as shown in FIGS. 1A-1C. However, unlike the encapsulant 120 of the package 100, the encapsulant 220 of the package 200 as shown in FIG. 2A has a shape different from the encapsulant 120 of the package 100 as shown in FIG. 1A. The encapsulant 220 includes a first surface 222, a second surface 223 laterally spaced apart to the left of the first surface 222 based on the orientation in FIG. 2A, and a third surface 225 laterally spaced apart to the right from the first surface 222 based on the orientation in FIG. 2A. The encapsulant 220 further includes a fourth surface 224 opposite to the first, second, and third surfaces 222, 223, 225. The first, second, and third surfaces 222, 223, 225 may be level surfaces, levels, exposed surfaces, outer surfaces, exterior surfaces, regions, surface portions, or some other like or similar type of surface.

A first sidewall 226 of the encapsulant 220 extends from the second surface 223 to the fourth surface 224. A second sidewall 228 of the encapsulant extends from the third surface 225 to the fourth surface 224. The first and second sidewalls 226, 228 are transverse to the first, second, and third surfaces 222, 223, 225.

A first dimension D14 extends from the first surface 222 to the fourth surface 224. A second dimension D15 extends from the second surface 223 to the fourth surface 224. A third dimension D7 extends from the third surface 225 to the fourth surface 224. The first dimension D14 is greater than the second and third dimensions D15, D7. In this embodiment of the package 200, the second dimension D15 is substantially equal to the third dimension D7. In some other alternative embodiments of the package 200, the second dimension D15 may be less than the first dimension D14 and greater than the third dimension D7. In some other alternative embodiments of the package 200, the second dimension D15 may be less than the first dimension D14 and less than the third dimension D7. For example, in some embodiments of the package 200, the dimension D14 of the package 200 may be the same or similar to in length as the first dimension D1 of the package 100 as shown in FIG. 1A.

A first angled surface 227 of the encapsulant 220 extends from the first surface 222 to the second surface 223 and separates the first surface 222 from the second surface 223. The first angled surface 227 is at a first angle θ1 relative to the second surface 223.

A second angled surface 229 of the encapsulant 220 extends from the first surface 222 to the third surface 225 and separates the first surface 222 from the second surface 223. The second angled surface 229 is at a second angle θ2 relative to the third surface 225. In this embodiment of the package 200, the second angle θ2 is substantially equal to the first angle θ1. In some other alternative embodiments of the package 200, the second angle θ2 may be different from the first angle θ1.

The first and second angled surfaces 227, 229 may be angled surfaces, angled levels, exposed angled surfaces, outer angled surfaces, exterior angled surfaces, angled regions, angled surface portions, or some other like or similar type of angled surface.

As shown in FIG. 2B, in this embodiment of the package 200, the first and second angled surfaces 227, 229 are separate and distinct surfaces that are separated from each other by the first surface 222. As shown in FIG. 2B, in this embodiment of the package 200, the second and third surfaces 223, 225 are separate and distinct surfaces that are separated from each other by the first surface 222, the first angled surface 227, and the second angled surface 229.

In at least one alternative embodiment of the package 200, two additional angled surfaces may be present. The two additional angled surfaces are spaced apart by the first surface 222, are transverse to the first and second angled surfaces 227, 229, and extend from the first angled surface 227 to the second angled surface 229. The two additional angled surfaces along with the first and second angled surfaces 227, 229 form a boundary or a perimeter around the first surface 222. The two additional angled surfaces and the first and second angled surfaces 227, 229 form a continuous, unitary boundary surface or perimeter surface around the first surface 222. Furthermore, in this at least one alternative embodiment of the package 200, the two additional angled surfaces are directly adjacent to two additional surfaces, respectively. The two additional surfaces are transverse to the second and third surfaces 223, 225, and the two additional surfaces extend from the second surface 223 to the third surface 225, respectively. The two additional surfaces along with the second and third surfaces 223, 225 form a boundary or perimeter around the two additional angled surfaces and the first and second angled surfaces 227, 229. The two additional surfaces and the second and third surfaces 223, 225 form a continuous, unitary boundary surface or perimeter surface around the two additional angled surfaces and the first and second angled surfaces 227, 229.

A first lead 230 of the package 200 includes a first end 232 outside of the encapsulant 220 and a second end 234 encased within the encapsulant 220. The first lead 230 is at the left-hand side of the package 200 based on the orientation in FIG. 2A. Unlike the first lead 130 of the package 100, the first lead 230 of the package 200 bends back towards the encapsulant 220 of the package 200 such that the first end 232 of the first lead 230 overlaps the second surface 223 of the encapsulant 220. The first lead 230 includes a first mounting surface 233 directly adjacent to the first end 232 of the first lead 230.

A second lead 236 of the package 200 includes a third end 238 outside of the encapsulant 220 and a fourth end 240 inside the encapsulant 220. The second lead 236 is at the right-hand side of the package 200 based on the orientation in FIG. 2A. Unlike the second lead 136 of the package 100, the second lead 236 of the package 200 bends back towards the encapsulant 220 of the package 200 such that the third end 238 of the second lead 236 overlaps the third surface 225 of the encapsulant 220. The second lead 236 includes a first mounting surface 235 directly adjacent to the first end 238 of the second lead 236.

The package 200 includes a dimension D11 extending from the first surface 222 of the encapsulant 220 to the mounting surface 233 of the first lead 230. The package 200 further includes a dimension D12 extending from the first surface 222 to the mounting surface 235 of the second lead 236. The dimension D11 is greater than the dimension D12.

A plurality of first conductive vias 242 extend into the first surface 222 of the encapsulant 220 to the contact surfaces 118 of the contact pads 116 of the die 102, which is encased within the encapsulant 220. The die 102 is coupled to the die pad 104 by the adhesive 106, and both the die pad 104 and the adhesive 106 are encased within the encapsulant 220. The first conductive vias 242 include a first conductive layer 244 and a second conductive layer 246.

The first conductive vias 242 of the package 200 are the same or similar to the first conductive vias 142 of the package 100. However, unlike the first conductive vias 142 in the package 100, the first conductive vias 242 in the package 200 are shorter relative to the first conductive vias 142 in the package 100. The first conductive layer 244 of the package 200 is the same or similar to the first conductive layer 144 of the package 100. The second conductive layer 246 of the package 200 is the same or similar to the second conductive layer 246 of the package 200. Accordingly, for the sake of brevity and simplicity of the present disclosure, the details of the first conductive vias 142, the first conductive layers 144, and the second conductive layers 246 will not be discussed in further detail herein.

A plurality of second conductive vias 248 extend into the encapsulant 220 and are coupled to respective ones of the contact pads 116 of the die 102, and to respective ends of the first and second leads 230, 236. For example, the second conductive via 248 at the left-hand side of the package 200 based on the orientation in FIG. 2A is coupled to the second end 234 of the first lead 230, and the second conductive via 248 at the right-hand side of the package 200 based on the orientation in FIG. 2A is coupled to the fourth end 240 of the second lead 236.

The second conductive via 248 at the left-hand side of the package 200 extends into the third surface 122 and the second surface 223. The second conductive via 248 at the right-hand side of the package 200 extends into the first surface 222 and the third surface 225 of the package 200.

Each one of the plurality of second conductive vias 248 includes a third conductive layer 250 and a fourth conductive layer 252 on and covering the third conductive layer 250. The third and fourth conductive layers 250, 252 of the package 200 are the same or similar to the third and fourth conductive layers 150, 152 of the package 100 as shown in FIG. 1A. Accordingly, for the sake of brevity and simplicity of the present disclosure, the details of the third and fourth conductive layers 150, 152 will not be discussed in further detail herein.

For the sake of simplicity and brevity of the present disclosure, only the details of the second conductive via 248 at the left-hand side of FIG. 2A will be discussed in further detail as follows. However, it will be readily appreciated that this discussion applies in a similar manner to similar features of the second conductive via 248 at the right-hand side of FIG. 2A with respect to the die 102 and the second lead 236.

The second conductive via 248 includes a first portion 248a, a second portion 248b, and a third portion 248c. The first, second, and third portions 248a, 248b, 248c include portions of the third conductive layer 250 and the fourth conductive layer 252. The first, second, and third portions 248a, 248b, 248c are integral each other, and, at least in this embodiment, the first, second, and third portions 248a, 248b, 248c are made of continuous and unitary materials of the third and fourth conductive layers 250, 252.

The first portion 248a extends into the second surface 223 of the encapsulant 220 to the first lead 230. The first portion 248a is coupled to the first lead 230. The first and second conductive layers 250, 252 are on the first lead 230.

The second portion 248b extends into the first surface 222 of the encapsulant 220 to the contact surface 118 of the left-most contact pad 116 of the die 102 based on the orientation in FIG. 2A. The second portion 248b is the same or similar shape and size as the first portion 248a.

The third portion 248c extends into first surface 222, the second surface 223, and the first angled surface 227, and the third portion 248c terminates within the encapsulant 220 before reaching the die 102 or the first lead 230. The third portion 248c extends from the first portion 248a to the second portion 248b and electrically couples the first portion 248a to the second portion 248b. A first section of the third portion 248c extends into the first angled surface 227 and is transverse to the first portion 248a to the second portion 248b of the second conductive via 248. The third portion 248c may be an electrical trace, an electrical connection, or some other similar or like electrical structure coupling the first and second portions 248a, 248b. In this embodiment, a second section of the third portion extends into the first surface 222 and a third section of the third portion extends into the second surface 223. In some other alternative embodiments, the third section may not be present, and, instead, the first and second sections may be the only sections present when the first portion 248a directly laterally adjacent to the first angled surface 227.

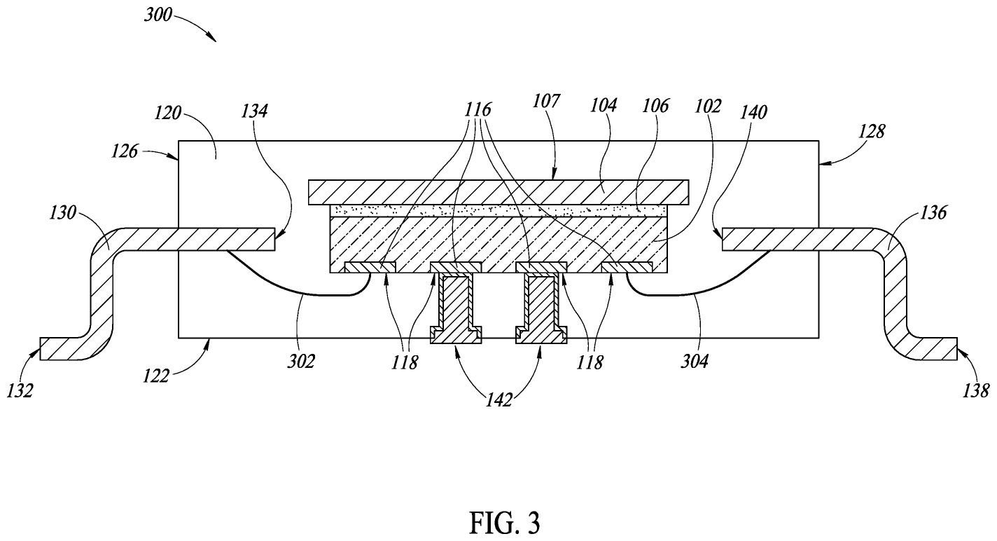

FIG. 3 illustrates a cross-section of an alternative embodiment of a package 300 having features that are the same or similar to the features of the package 100 as shown in FIG. 1A-1C. For the sake of simplicity and brevity of the present disclosure, only differences or additional features of the package 300 as compared to the package 100 as shown in FIG. 1A-1C will be discussed in further detail herein. The same reference numerals will be utilized to indicate features of the package 300 that are the same or similar to those features as described earlier with respect to the package 100 as shown in FIGS. 1A-1C.

Unlike the package 100, the package 300 includes a first electrical connection 302 and a second electrical connection 304 that are encased within the encapsulant 120. The first and second electrical connections 302, 304 have replaced the second conductive vias 148 of the package 100 as shown in FIGS. 1A-1C. The first and second electrical connections 302, 304 may be wires, wire bonds, or some other suitable or like conductive structure or component coupling the first and second leads 130, 136, respectively, to respective ones of the contact pads 116 of the die 102.

A first end of the first electrical connection 302 is coupled to the contact surface 118 of the left-most contact pad 116 of the die 102 based on the orientation of the package 300 as shown in FIG. 3. A second end of the first electrical connection 302 is coupled to a surface of the first lead 130.

A first end of the second electrical connection 304 is coupled to the contact surface 118 of the right-most contact pad 116 of the die 102 based on the orientation of the package 300 as shown in FIG. 3. A second end of the second electrical connection 304 is coupled to a surface of the second lead 136.

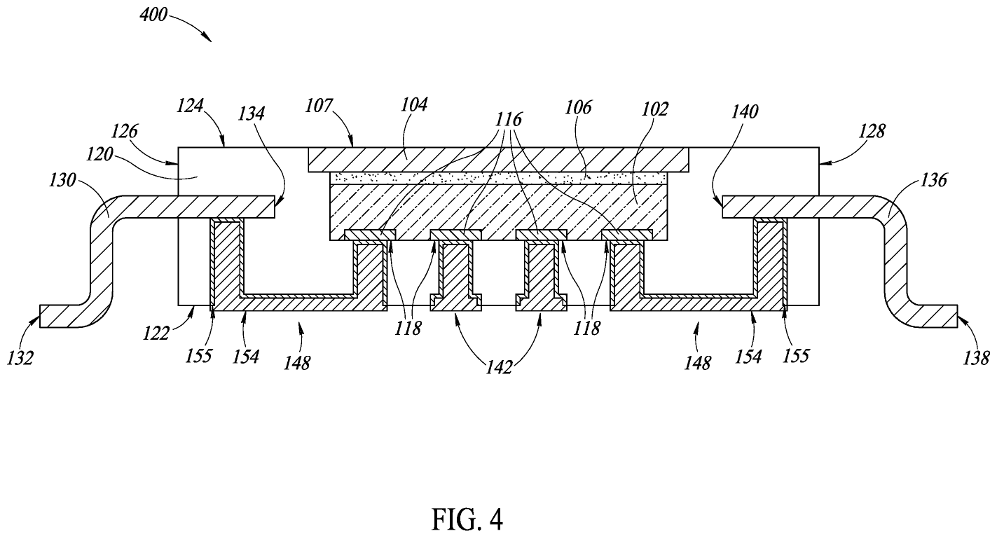

FIG. 4 illustrates a cross-section of an alternative embodiment of a package 400 having features that are the same or similar to the features of the package 100 as shown in FIGS. 1A-1C. For the sake of simplicity and brevity of the present disclosure, only differences or additional features of the package 400 as compared to the package 100 as shown in FIGS. 1A-1C will be discussed in further detail herein. The same reference numerals will be utilized to indicate features of the package 400 that are the same or similar to those features as described earlier with respect to the package 100 as shown in FIGS. 1A-1C.

Unlike the package 100 in which the second surface 107 of the die pad 104 is covered by the encapsulant 120, the second surface 107 of the die pad 104 is substantially coplanar with the fourth surface 124 of the encapsulant 120 of the package 400. The encapsulant 120 in the package 400 is less thick extending from the third surface 122 to the fourth surface 124 as compared to a similar thickness of the encapsulant 120 of the package 100 as shown in FIGS. 1A-1C.

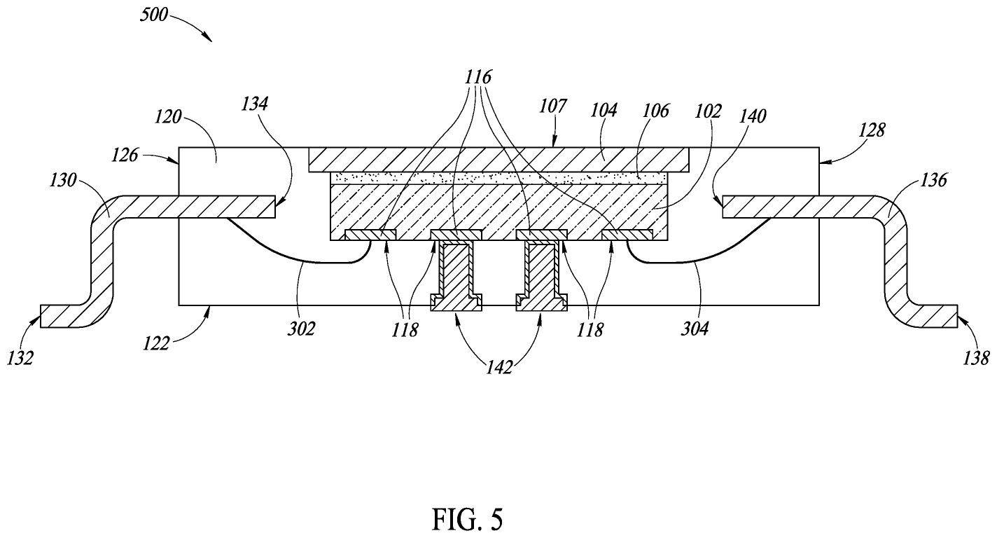

FIG. 5 illustrates a cross-section of an alternative embodiment of a package 500 that has features that are the same or similar to the feature of the package 300 as shown in FIGS. 1A-1C. For the sake of simplicity and brevity of the present disclosure, only differences or additional features of the package 500 as compared to the package 300 as shown in FIG. 3 will be discussed in further detail herein. The same reference numerals will be utilized to indicate features of the package 500 that are the same or similar to those features as described earlier with respect to the package 300 as shown in FIG. 3.

Unlike the package 300 in which the second surface 107 of the die pad 104 is covered by the encapsulant 120, the second surface 107 of the die pad 104 is substantially coplanar with the fourth surface 124 of the encapsulant 120 of the package 500. The encapsulant 120 in the package 500 is less thick extending from the third surface 122 to the fourth surface 124 as compared to a similar thickness of the encapsulant 120 of the package 300 as shown in FIG. 3.

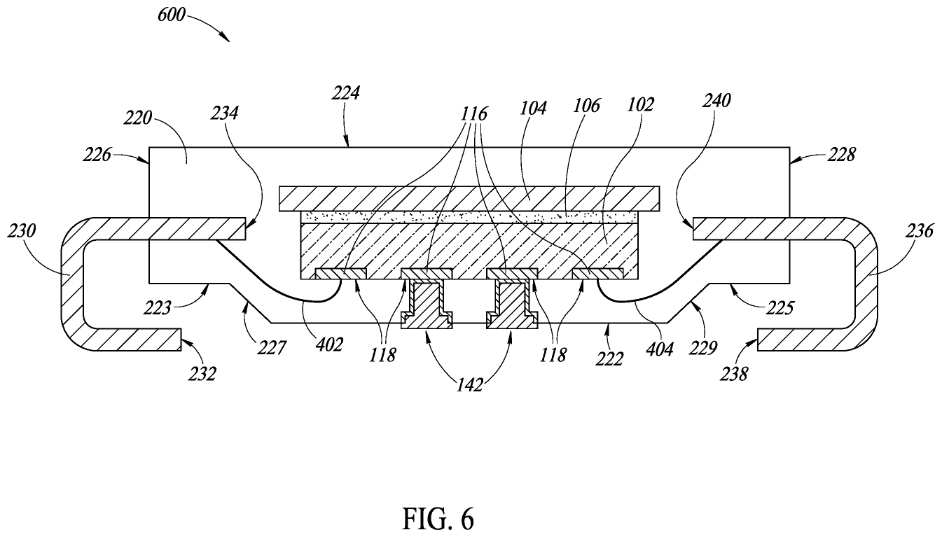

FIG. 6 illustrates a cross-section of an alternative embodiment of a package 600 having features that are the same or similar to the feature of the package 200 as shown in FIGS. 2A and 2B. For the sake of simplicity and brevity of the present disclosure, only differences or additional features of the package 600 as compared to the package 200 as shown in FIGS. 2A and 2B will be discussed in further detail herein. The same reference numerals will be utilized to indicate features of the package 600 that are the same or similar to those features as described earlier with respect to the package 200 as shown in FIGS. 2A and 2B.

Unlike the package 200, the package 600 includes a first electrical connection 402 and a second electrical connection 404 that are encased within the encapsulant 120. The first and second electrical connections 402, 404 have replaced the second conductive vias 248 of the package 200 as shown in FIGS. 2A and 2B. The first and second electrical connections 402, 404 may be wires, wire bonds, or some other suitable or like conductive structure or component coupling the first and second leads 230, 236, respectively, to respective ones of the contact pads 116 of the die 102.

A first end of the first electrical connection 402 is coupled to the contact surface 118 of the left-most contact pad 116 of the die 102 based on the orientation of the package 600 as shown in FIG. 6. A second end of the first electrical connection 402 is coupled to a surface of the first lead 230. In this embodiment of the package 600, the first electrical connection 402 overlaps the first surface 222, the second surface 223, and the first angled surface 227. In some other alternative embodiments of the package 600, the first electrical connection 402 may not overlap with the first surface 223 if the second end of the first electrical connection 402 is coupled to the surface of the first lead 230 at a location further to the right than as shown in FIG. 6. For example, if the second end 234 of the first lead 230 extends further into the package 600 than as shown, then the first electrical connection 230 may not overlap with the first surface 223 of the encapsulant 220

A first end of the second electrical connection 404 is coupled to the contact surface 118 of the right-most contact pad 116 of the die 102 based on the orientation of the package 600 as shown in FIG. 6. A second end of the second electrical connection 404 is coupled to a surface of the second lead 236. In this embodiment of the package 600, the second electrical connection 404 overlaps the first surface 222, the third surface 225, and the second angled surface 229. In some other alternative embodiments of the package 600, the second electrical connection 404 may not overlap with the first surface 223 if the second end of the second electrical connection 404 is coupled to the surface of the second lead 236 at a location further to the left than as shown in FIG. 6. For example, if the fourth end 240 of the second lead 236 extends further into the package 600 than as shown, then the second electrical connection 404 may not overlap with the third surface 225 of the encapsulant 220.

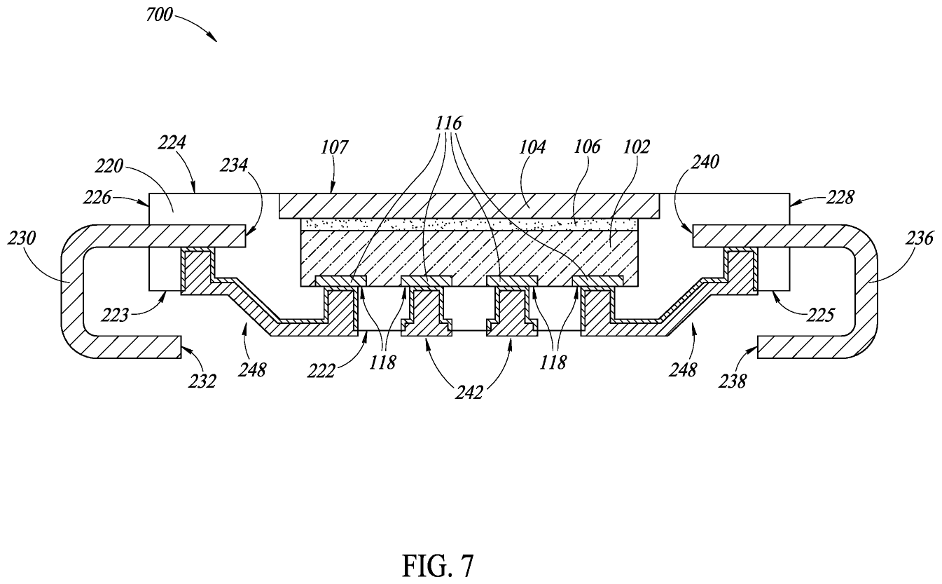

FIG. 7 illustrates a cross-section of an alternative embodiment of a package 700 having features that are the same or similar to the feature of the package 200 as shown in FIGS. 2A and 2B. For the sake of simplicity and brevity of the present disclosure, only differences or additional features of the package 700 as compared to the package 200 as shown in FIGS. 2A and 2B will be discussed in further detail herein. The same reference numerals will be utilized to indicate features of the package 700 that are the same or similar to those features as described earlier with respect to the package 200 as shown in FIGS. 2A and 2B.

Unlike the package 200 in which the second surface 107 of the die pad 104 is covered by the encapsulant 220, the second surface 107 of the die pad 104 is substantially coplanar with the second surface 224 of the encapsulant 220 of the package 700. The encapsulant 220 in the package 700 is less thick extending from the first surface 222 to the second surface 224 as compared to a similar thickness of the encapsulant 220 of the package 200 as shown in FIGS. 2A and 2B.

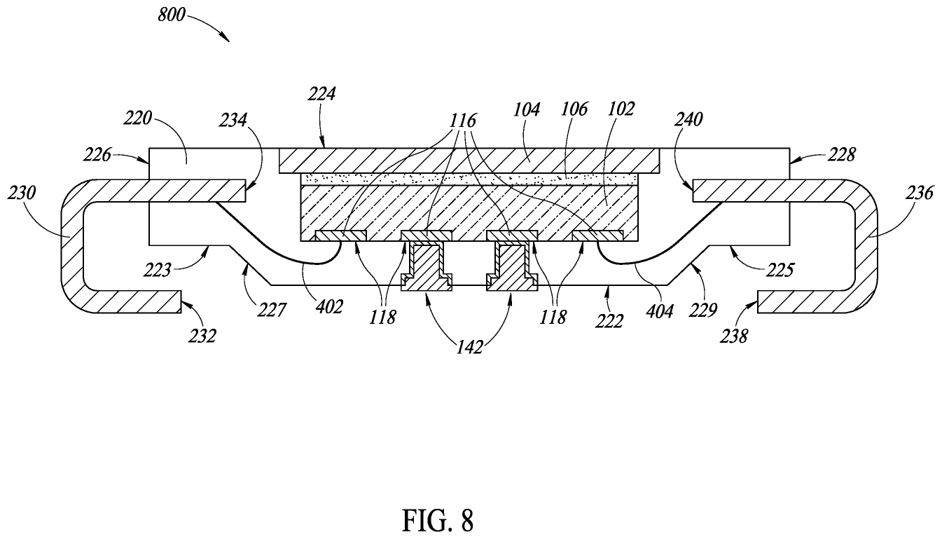

FIG. 8 illustrates a cross-section of an alternative embodiment of a package 800 that has features that are the same or similar to the feature of the package 600 as shown in FIG. 6. For the sake of simplicity and brevity of the present disclosure, only differences or additional feature of the package 800 as compared to the package 600 as shown in FIG. 6 will be discussed in further detail herein. The same reference numerals will be utilized to indicate features of the package 800 that are the same or similar to those features as described earlier with respect to the package 600 as shown in FIG. 6.

Unlike the package 600 in which the second surface 107 of the die pad 104 is covered by the encapsulant 220, the second surface 107 of the die pad 104 is substantially coplanar with the second surface 224 of the encapsulant 220 of the package 800. The encapsulant 220 in the package 700 is less thick extending from the first surface 222 to the second surface 224 as compared to a similar thickness of the encapsulant 220 of the package 200 as shown in FIGS. 2A and 2B.

FIG. 9 illustrates a cross-section of the package 100 mounted, coupled, or adhered to a substrate 900. The substrate 900 may be a printed circuit board (PCB), a support substrate, or some other suitable electronic structure or component. The substrate 900 includes a first surface 902 and a second surface 904 opposite to the first surface 902. A plurality of bond pads 906 are at the first surface 902 of the substrate 900.

A plurality of solder balls 908 couple the package 100 to the plurality of bond pads 906 of the substrate 900. For example, the left-most solder ball 908, which is based on the orientation of the package 100 as shown in FIG. 9, couples the first lead 130 to the left-most bond pad 906, which is based on the orientation of the package 100 as shown in FIG. 9. The right-most solder ball 908, which is based on the orientation of the package 100 as shown in FIG. 9, couples the second lead 136 to the right-most bond pad 906, which is based on the orientation of the package 100 as shown in FIG. 9. The centrally located solder balls 908 positioned between the left-most solder ball 908 and the right-most solder ball 908 couple the first conductive vias 142 to the centrally located bond pads 906.

The third surface 122 of the package 100 is spaced apart from the first surface 902 of the substrate 900 by a dimension D8. The dimension D8 is determined by the dimension D9 and D10 as discussed earlier with respect to the package 100 as shown in FIGS. 1A-1C. Similarly, if the package 200 was mounted to the substrate 900, the dimension D8, which would be between the first surface 222 of the package 200 and the first surface 902 of the substrate 900. The dimension D8 is determined by the dimensions D11 and D12 as discussed earlier with respect to the package 200 as shown in FIGS. 2A and 2B. For example, the dimension D8 may range from 20-μm (micrometers) to 80-μm (micrometers).

While the following discussion will be with respect to the package 100 coupled to the substrate 900, it will be readily appreciated that the following discussion will similarly apply to the other packages 200, 300, 400, 500, 600, 700, 800 of the present disclosure. As shown in FIG. 9, the mounting surfaces 133, 135 of the first and second leads 130, 136 of the package 100 are spaced further away from the second surface 110 of the die 102 than the exposed surfaces 158 of the first conductive vias 142 in a direction from the second surface 110 of the die 102 to the third surface 122 of the encapsulant 120. When the package 100 is mounted to the contact pads 906 of the printed circuit board 900 utilizing the solder balls 908. The first and second leads 130, 136 may be partially or fully encased within their respective or corresponding solder balls 908, and portions of the first conductive vias 142 that partially protrude from the third surface 122 of the encapsulant 120 may be partially or fully encased within their respective or corresponding solder balls 908 as well.

The solder ball 908 coupled to the left-most first conductive via 142 based on the orientation in FIG. 9 is spaced apart from the left-most solder ball 908 coupled to the first lead 130 by a dimension D13. To increase the dimension D13, the lead 130 may be increased in length, and, to decrease the dimension D13, the first lead 130 may be decreased in length. It will be readily appreciated that this discussion can similarly be applied to the second lead and other respective solder balls 908 of the plurality of solder balls 908.

The dimensions D8, D13 may be selected based on the environmental characteristics, quantities, and qualities that the package 100 may be exposed. For example, if the package 100 is exposed to rapid changes in temperature from cold to hot or vice versa, the components of the package 100 will expand or contract. For example, the encapsulant 120, the leads 130, 136, and the first and second conductive vias 142, 148 may expand and contract by differing amounts and at different speeds. These differences in expansion and contraction between these components of the package 100 may cause cracks, breaks, or delamination of the leads 130, 136 with the solder balls 908. This expansion and contraction at the sidewalls 126, 128 is generally different from the amount of expansion and contraction at the first conductive vias 142, and this difference in expansion and contraction can increase the likelihood of failure or defects. However, by optimizing the dimensions D8, D13, the first and second leads 130, 136 may absorb stresses and strains caused by the expansion and contraction near the sidewalls 126, 128 of the encapsulant and reduce the likelihood of failure within the package 100 due to these types of defects.

FIGS. 10A-10C illustrate cross-sectional views of a method of manufacturing 1000 the embodiment of the package 100 as shown in FIGS. 1A-1C. As shown in FIG. 10A, a plurality of encapsulant portions 1002 are formed around and on a leadframe 1004. The leadframe 1004 includes a plurality of die pad portions 1006 and a plurality of lead portions 1008. Each respective one of the plurality of encapsulant portions 1002 encases corresponding ones of a plurality of die 1010, a plurality of adhesive portions 1012, and the plurality of die pad portions 1006 of the leadframe 1004. The encapsulant portions 1002 further encase ends 1014 of the plurality of lead portions 1008.

The encapsulant portions 1002 correspond to the encapsulant 120 as described earlier with respect to the package 100 as shown in FIGS. 1A-1C. The die pad portions 1006 and the lead portions 1008, respectively, correspond to the die pad 104 and the first and second leads 130, 136, respectively, as described earlier with respect to the package 100 as shown in FIGS. 1A-1C. The die 1010 corresponds to the die 102 as described earlier with respect to the package 100 as shown in FIGS. 1A-1C. The adhesive portions 1012 correspond to adhesive 106 as described earlier with respect to the package 100 as shown in FIGS. 1A-1C. The encased ends 1014 in the encapsulant portions 1002 correspond to the ends 134, 140 of the first and second leads 130, 136 of the package 100 as shown in FIGS. 1A-1C.

In the step shown in FIG. 10A, the adhesive portions 1012 are coupled to the die pad portions 1006 of the leadframe 1004 and the die 1010 are then coupled to the adhesive portions 1012. The adhesive portions 1012 may be formed by applying the adhesive portions 1012 utilizing a machine that dispenses, extrudes, sputters, or applies the adhesive portions 1012 by some other like or suitable technique to the die pad portions 1006. The die 1010 may then be placed onto the adhesive portions 1012 by a pick and place machine, which picks up the die 1010 and places the die 1010 to the adhesive portions 1012. This process couples the die 1010 to the die pad portions 1006 by the adhesive portions 1012.

After the die 1010 have been coupled to the die pad portions 1006 utilizing the adhesive portions 1012, the encapsulant portions 1002 are formed encasing the die pad portions 1006, the die 1010, the adhesive portions 1012, and the ends 1014 of the lead portions 1008. The encapsulant portions 1002 may be formed by an injection molding process, a compression molding process, a mold tool molding process, or some other like or suitable technique for forming the encapsulant portions 1002. For example, a first (e.g., upper) mold tool (not shown) may be positioned on a first side of the leadframe 1004 and a second (e.g., lower) mold tool (not shown) may be positioned on a second side of the leadframe 1004. Once the first and second mold tools are positioned, an encapsulant may then be injected into spaces between the first and second mold tools forming the encapsulant portions 1002 around the die pad portions 1006, the die 1010, the adhesive portions 1012, and the ends 1014 of the lead portions 1008. The encapsulant portions 1002 may then be cured within the first and second molding tools such that the encapsulant portions 1002 harden and become solidified enough such that when the first and second mold tools are removed, the encapsulant portions 1012 maintain their shape without deforming. The encapsulant may be a molding compound, a resin, an epoxy, or some other similar or suitable material for encasing the die pad portions 1006, the die 1010, the adhesive portions 1012, and the ends 1014 of the lead portions 1008.

As shown in FIG. 10B, after the encapsulant portions 1002 have been formed, the encapsulant portions 1002 are patterned utilizing a laser direct structuring (LDS) process. The encapsulant portions 1002 are a doped encapsulant material, and the doped encapsulant material includes additive materials that are activated (e.g., become electrically conductive) when exposed to a laser. For example, the additive material may be a copper material, a silver material, an alloy material, or some other type of material that becomes electrical conductive when exposed to the laser. For example, the additive material may be a doping material in the encapsulant portions 1002 such as a non-conductive inorganic metallic compound. When the non-conductive inorganic metallic compound within the encapsulant portions 1002 is exposed to a laser, a chemical reaction occurs and the non-conductive inorganic metallic compound becomes a conductive metallic compound.

For example, the encapsulant portions 1002 may be made of an LDS compatible polymer such as KMC-9200 from Shin Etsu, EME-L series from Sumikon, or may be some other type of LDS compatible polymer, resin, molding compound, or encapsulant material.

As shown in FIG. 10B, a plurality of first openings 1016 and a plurality of second openings 1018 are formed in the encapsulant portions 1002 extending into a surface 1020 of the encapsulant portions 1002 to surfaces 1023 of contact pads 1022 of the die 1010. The surface 1020 corresponds to the third surface 122 of the encapsulant 120 of the package 100 as shown in FIGS. 1A-1C. The contact pads 1022 of the die 1010 correspond to the contact pads 1022 of the die 102 of the package 100 as shown in FIGS. 1A-1C. The surfaces 1023 of the contact pads 1022 correspond to the surfaces 118 of the contact pads 116 of the package 100 as shown in FIGS. 1A-1C.

The pluralities of first and second openings 1016, 1018 are formed by exposing portions of the encapsulant portions 1002 to a laser (not shown) by moving the laser across surfaces 1020 of the encapsulant portions 1002. The laser removes the portions of the encapsulant portions 1002 forming the first and second openings 1016, 1018. Successively with forming the pluralities of first and second openings 1016, 1018, a plurality of first conductive layers 1024 and a plurality of second conductive layers 1026 are formed. The plurality of first conductive layers 1024 line the plurality of first openings 1016 and the plurality of second conductive layers 1026 line the plurality of second openings 1018. The first and second conductive layers 1024, 1026 are on and coupled to surfaces 1023 of the contact pads 1022.

As the laser moves across the surface 1020 removing the portions of the encapsulant portions 1002, surfaces formed defining the first and second openings 1016, 1018 by the laser may be micro-rough surfaces in which small micro-divots, micro-recesses, and micro-voids are present. These micro-rough surfaces allow for a conductive material to be more readily formed and adhered to these micro-rough surfaces of the encapsulant portions 1002 in the first and second openings 1016, 1018 during a plating step, which will be discussed in further detail at least with respect to FIG. 10C.

The laser is moved along the surfaces 1020 of the encapsulant portions in a selected or programmed manner to forming the first and second openings 1016, 1018. However, the laser may be moved along at different speeds and held stationary at locations along the surfaces 1020 for different amounts of times to form the first and second openings. For example, the laser may move along the surfaces 1020 of the encapsulant portions 1002 at locations where the first and second openings 1016, 1018 are shallower relative to other location that are deeper at a first speed. Alternatively, the laser may move along the surfaces 1020 of the encapsulant portions 1002 at locations where the first and second openings 1016, 1018 are deeper at a second speed. The first speed being greater than the second speed. Similarly, the laser may be held at locations where the first and second openings 1016, 1018 are shallower for a first period of time, and the laser may be held at locations where the first and second openings 1016, 1018 are deeper for a second period of time. The first period of time is less than the second period of time. In other words, the laser successively moves along the surfaces 1020 of the encapsulant portions 1002 in a selected manner at various speeds and selected periods of time at various locations to form the first and second openings 1016, 1018 relative to sizes and shapes of the first and second openings 1016, 1018.

The first conductive layers 1024 correspond to the first conductive layers 144 of the package 100 as shown in FIGS. 1A-1C. The second conductive layers 1026 correspond to the third conductive layers 150 of the package 100 as shown in FIGS. 1A-1C. The first openings 1016 correspond to the first conductive vias 142 of the package 100 as shown in FIGS. 1A-1C. The second openings 1024 correspond to the second conductive vias 148 of the package 100 as shown in FIGS. 1A-1C.

After the first and second openings 1016, 1018 and the first and second conductive layers 1024, 1026 are formed, a plating process is carried out forming third and fourth conductive layers 1028, 1030, respectively, in the first and second openings 1016, 1018, respectively, on the first and second conductive layers 1024, 1026, respectively. The third and fourth conductive layers 1028, 1030, respectively, fill the first and second openings 1016, 1018, respectively. The results of this plating process are readily seen in FIG. 10C in which a first conductive via 1032 and second conductive via 1034 are in the encapsulant 1002 and exposed at the surface 1022 of the encapsulant 1002. The first conductive vias 1032 include ones of the first and third conductive layers 1024, 1028, and the second conductive vias 1034 include ones of the second and fourth conductive layers 1024, 1034.

The third conductive layer 1028 corresponds to the second conductive layer 146 of the first conductive vias 142 of the package 100 as shown in FIGS. 1A-1C. The fourth conductive layer 1030 corresponds to the fourth conductive layer 152 of the package 100 as shown in FIGS. 1A-1C. The first conductive vias 1032 correspond to the first conductive vias 142 of the package 100 as shown in FIGS. 1A-1C. The second conductive vias 1034 correspond to the second conductive vias 148 of the package 100 as shown in FIGS. 1A-1C.

The plating process may be an electroless or chemical plating process in which the components as shown in FIG. 10B are placed within a bath containing a conductive material such as a silver material, a gold material, a nickel material, an alloy material, or some other conductive material suitable for an electroless plating process or similar plating process. When in the electroless plating bath, the conductive material in the electroless plating bath is attracted to and coupled to the first and second conductive layers 1024, 1026. After the electroless plating process is completed, the third and fourth conductive layers 1028, 1030 are formed on and coupled to the first and second conductive layers 1024, 1026, respectively. After the electroless plating process is completed, the third and fourth conductive layers 1028, 1030 are formed in and fill the first and second openings 1016, 1018, respectively.

By forming the third and fourth conductive layers 1028, 1030, the first and second conductive vias 1032, 1034 are formed, respectively. The first and second conductive vias 1028, 1030 are electrical connections that the contact pads 1022 to the lead portions 1008 of the leadframe 1004.

After the third and fourth conductive layers 1028, 1030 are formed to form the first and second conductive vias 1032, 1034, the lead portions 1008 are cut by a singulation tool such as a saw, a laser, or some other suitable or like singulation tool. The leads portions 1008 are singulated at a dotted line 1036 as shown in FIG. 10C. The singulation of the lead portions 1008 also singulates the packages 100. The lead portions 1008 may be bent during the singulation process or may be bent in an additional step. The lead portions 1008 once singulated are the same or similar to the first and second leads 130, 136 as shown in FIGS. 1A-1C.

The alternative embodiment of the package 400 as shown in FIG. 4 may be formed by an alternative embodiment of the method of manufacturing 1000 that is the same or similar as shown in FIGS. 10A-10C. However, at some point during the method of manufacturing 1000 or at the end of the method of manufacturing 1000, an additional grinding step in which a surface 1003 of the encapsulant 1002 opposite to the surface 1022 is grinded down. During this back grinding step, a surface 1007 of the die pad 1006 is uncovered and exposed such that the surface 1007 of the die pad 1006 is substantially coplanar with the surface 1003 of the encapsulant.

The surface 1007 of the die pad 1006 corresponds to the surface 107 of the die pad 104 of the package 400 as shown in FIG. 4. The surface 1003 of the encapsulant 1002 corresponds to the surface 124 of the encapsulant 120 as shown in FIG. 4.

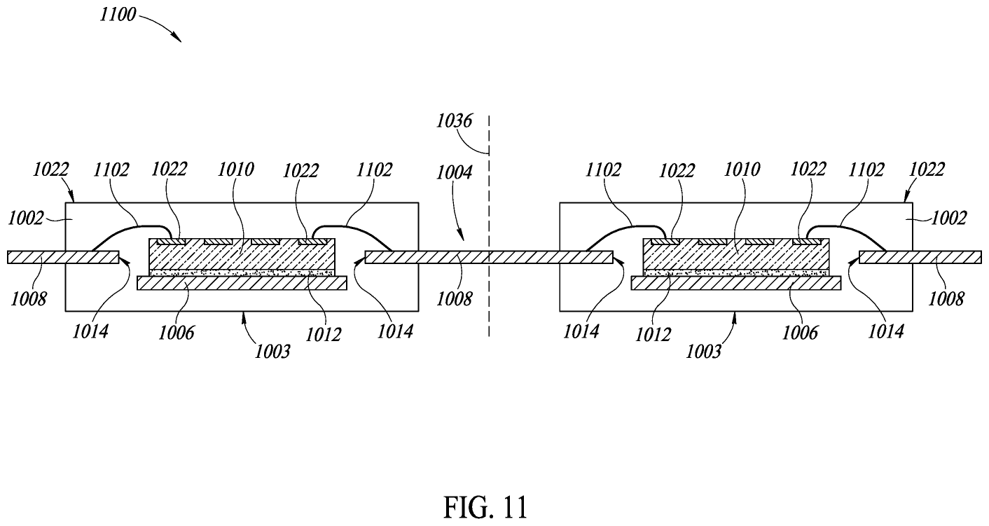

FIG. 11 is directed to an alternative embodiment of a method of manufacturing 1100 of the alternative embodiment of the package 300 as shown in FIG. 3. The method of manufacturing 1100 is the same or similar to the method of manufacturing 1000 the package 100 as shown in FIGS. 10A-10C. Accordingly, for the sake of simplicity and brevity of the present disclosure, only different or additional features of the method of manufacturing 1100 with respect to the method of manufacturing 1000 will be discussed in additional detail herein.

Unlike the method of manufacturing 1000 of the package 100 as shown in FIGS. 10A-10C, a plurality of electrical wires 1102 are formed coupling at least one of the contact pads 1022 to at least one of the lead portions 1008. The electrical wires 1102 are then encased and covered by forming the encapsulant portions 1002, which is the same or similar to forming the encapsulant portions 1002 as discussed with respect to FIG. 10A.

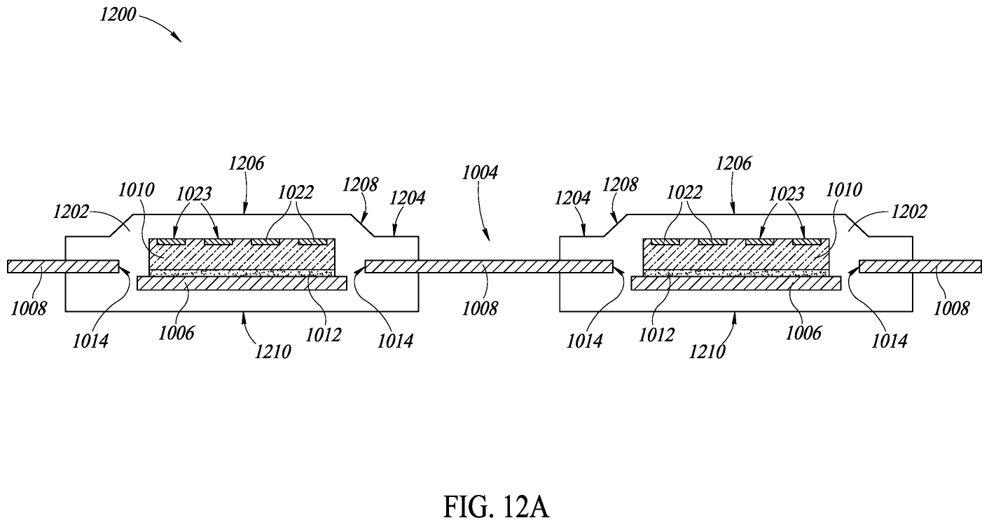

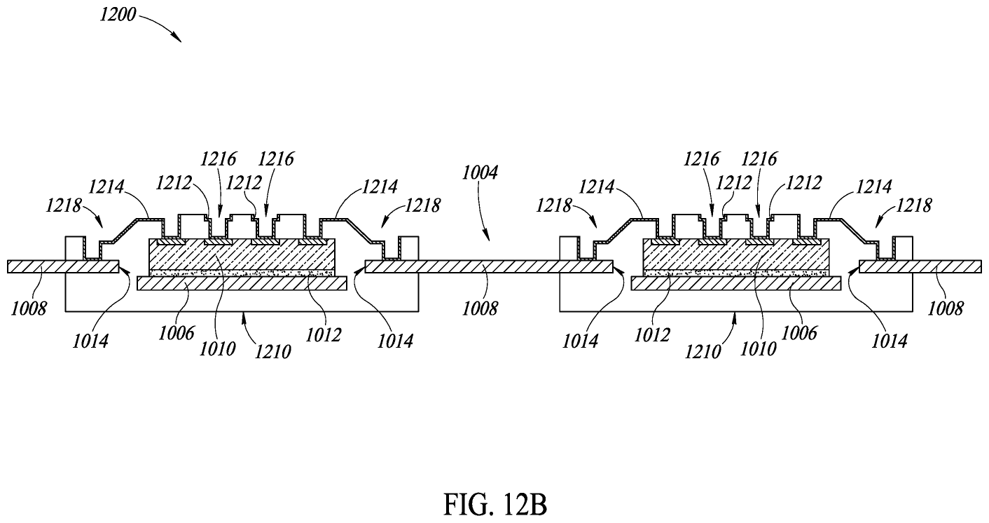

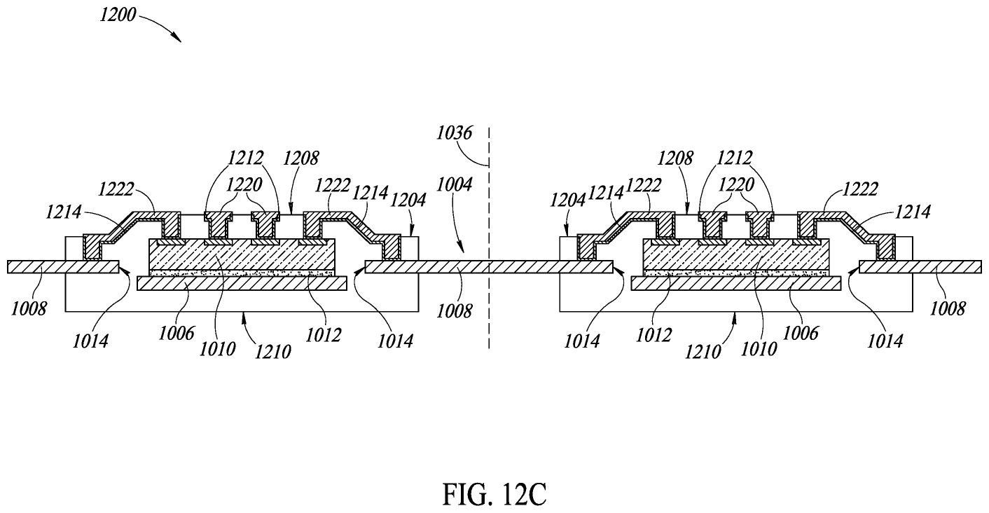

FIGS. 12A-12C illustrate cross-sectional views of an embodiment of a method of manufacturing 1200 the embodiment of the package 200 as shown in FIGS. 2A and 2B. The same reference numerals will be utilized to indicate features during the method of manufacturing 1000 that are the same or similar to those features as described earlier with respect to the package 100 as shown in FIGS. 1A-1C. The method of manufacturing 1200 the package 200 is the same or similar to the method of manufacturing 1000 that package 100 as shown in FIGS. 10A-10C. The same or similar reference numerals will be utilized in FIGS. 12A and 12B for the same or similar features as shown in FIGS. 10A-10C. Accordingly, for the sake of simplicity and brevity of the present disclosure, only different or additional features will be discussed in further detail herein.

Like the method of manufacturing 1000, encapsulant portions 1202 are formed in the same or similar manner as the encapsulant portions 1002. However, unlike the encapsulant portions 1202, the encapsulant portions 1202 are formed having a first surface 1204, a second surface 1206, an angled surface 1208 that extends from the first surface 1204 to the second surface 1206, and a fourth surface 1210 that is opposite to the first, second, and angled surfaces 1204, 1206, 1208. Although the encapsulant portions 1202 have a shape and size different from the encapsulant portions 1002 as shown in FIGS. 10A-10C, otherwise, the encapsulant portions 1202 as shown in FIGS. 12A and 12B are the same or similar to the encapsulant portions 1002 as shown in FIGS. 10A-10C

After the encapsulant portions 1202 are formed as shown in FIG. 12A, the encapsulant portions 1202 are patterned utilizing an LDS process, which is the same or similar to the LDS process as shown and discussed earlier with respect to FIG. 10B. Accordingly, for the sake of simplicity and brevity of the present disclosure, only differences or additional features of the LDS process in FIG. 12B as compared to the LDS process in FIG. 10B will be discussed in further detail herein.

A laser is moved along the first surface 1204, the second surface 1206, and the angled surface 1208 in the same or similar manner as the laser moved along the surface 1022 of the encapsulant portions 1002. Similarly to forming the first and second conductive layers 1024, 1026 and the first and second openings 1016, 1018 as shown in FIG. 10B, first and second conductive layers 1212, 1214 are formed successively with first and second openings 1216, 1218. The first and second conductive layers 1212, 1214 line the first and second openings 1216, 1218, respectively.

After the first and second conductive layers 1212, 1214 and the first and second openings 1216, 1218 are formed, a plating step is carried out forming third conductive layers 1220 and fourth conductive layers 1222 that fill the first and second openings 1216, 1218, respectively. The third conductive layers 1220 are on and coupled to respective ones of the first conductive layers 1212, and the fourth conductive layers 1222 are on and coupled to respective ones of the second conductive layers 1214. The third and fourth conductive layers 1220, 1222 are formed in the same or similar manner as the third and fourth conductive layers 1028, 1030 as discussed earlier with respect to FIG. 10C. Accordingly, for the sake simplicity and brevity of the present disclosure, forming the third and fourth conductive layers 1220, 1222 will not be discussed in further detail herein.

After the third and fourth conductive layers 1220, 1222 are formed, the lead portions 1008 are singulated at the dotted line 1036 in the same or similar manner as discussed earlier with respect to FIG. 10C for forming the packages 100 of the present disclosure. Accordingly, for the sake simplicity and brevity of the present disclosure, the singulation of the lead portions 1008 will not be discussed in further detail herein.

Even though methods of manufacturing each and every one of the embodiments of the packages 100, 200, 300, 400, 500, 600, 700, 800 are not discussed in detail herein, it will be readily appreciated that the above steps and processes in the embodiments of the methods of manufacturing 1000, 1100, 1200 may be reorganized or carried out in slightly different manners to form the packages 100, 200, 300, 400, 500, 600, 700, 800 as well as additional embodiments not shown in the present disclosure.

The methods of manufacturing 1000, 1100, 1200 reduce costs for manufacturing the packages 100, 200, 300, 400, 500, 600, 700, 800 as compared to conventional methods of manufacturing that utilize multiple steps for forming multi-layer packages, utilizing the LDS process as set forth within the present disclosure is relatively inexpensive compared to those conventional methods of manufacturing. For example, conventional methods of manufacturing packages without the LDS process as described within the present disclosure may include a combination of bath steps, etching steps, patterning steps, deposition steps, singulation steps, and other suitable manufacturing steps. However, as more and more steps are added into the conventional methods of manufacturing to form ever increasingly complex packages the process for utilizing these conventional methods of manufacturing increases significantly. Accordingly, being able to utilize the LDS process as descried within the present disclosure to form the packages 100, 200, 300, 400, 500, 600, 700, 800 of the present disclosure reduces costs and reduces manufacturing time as there are less steps relative to the conventional methods of manufacturing other similar or like conventional packages.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a die pad;
a die on and coupled to the die pad, the die including a first conductive pad and a second conductive pad;
a resin around the die and the die pad, the resin including a sidewall and a first surface transverse to the sidewall;
a lead extending into the sidewall of the resin, the lead having a first end in the resin between the die and the sidewall of the resin;
a conductive trace at the first surface of the resin;
a first conductive via extending into the first surface of the resin to the first conductive pad;
a second conductive via extending through the resin from the second conductive pad to the conductive trace; and
a third conductive via extending through the resin from the lead to the conductive trace.

2. The device of claim 1, wherein the conductive via further includes an exposed surface at the first surface of the resin.

3. The device of claim 1, wherein the lead further includes a second end opposite to the first end, the second end being external to the resin.

4. The device of claim 3, wherein the second end overlaps the first surface of the resin.

5. The device of claim 1, wherein the resin is doped with a non-conductive metallic inorganic compound.

6. The device of claim 1, wherein:
the resin has a second surface opposite to the first surface; and
the die pad has a third surface exposed from the second surface of the resin.

7. The device of claim 1, wherein the first surface further includes:
a first surface portion spaced apart from the die in a first direction directed from the die towards the first surface;
a second surface portion around the first surface portion, the second surface portion being closer to the die in the first direction than the first surface portion; and
an angled surface portion extending from the first surface portion to the second surface portion, the angled surface being transverse to the first and second surface portions.

8. The device of claim 7, wherein the lead further includes a second end opposite to the first end, the second end overlaps the second surface portion.

9. A device, comprising:
a resin including a first side, a second side opposite to the first side, and a sidewall that is transverse to the first and second sides, the sidewall extending from the first side to the second side;
a die pad in the resin including a mounting surface;
a die in the resin, the die coupled to the mounting surface of the die pad, and the die including an active surface, a first conductive pad at the active surface, and a second conductive pad at the active surface;
a lead having a first end in the resin between the die and the sidewall of the resin, and the first end being between the mounting surface of the die pad and the active surface of the die;
a conductive wire within the resin extending from the lead to the first conductive pad of the die, the conductive wire coupled to the first conductive pad and the lead;
a conductive via extending into the first side of the resin to the second conductive pad of the die, the conductive via coupled to the second conductive pad, the conductive via including an exposed surface at the first side, the exposed surface being aligned with the die.

10. The device of claim 9, wherein the first side further includes:
a first surface spaced apart from the die in a first direction directed from the die towards the first side;
a second surface around the first surface, the second surface being closer to the die in the first direction than the first surface; and
an angled surface extending from the first surface to the second surface, the angled surface being transverse to the first and second surfaces.

11. The device of claim 10, wherein the lead further includes a second end opposite to the first end, the second end overlapping the second surface.

12. The device of claim 11, wherein the conductive wire overlaps with the angled surface.

13-22. (canceled)

23. A method, comprising:
coupling a die to a die pad portion of a leadframe;
forming a resin doped with an additive conductive material on the die and the die pad;
forming a first opening in the resin extending to a central region of the die with a laser;
forming a first conductive layer to line the first opening and on a surface of a first contact pad at the central region of the die; and
covering the first conductive layer with a conductive material by forming the conductive material on the first conductive layer.

24. The method of claim 23, wherein covering the first conductive layer with the conductive material further includes plating the first conductive layer with the conductive material.

25. The method of claim 23, wherein forming the first conductive layer occurs concurrently with forming the opening by utilizing the laser.

26. (canceled)

27. The method of claim 23, wherein forming the resin doped with the additive conductive material on the die and the die pad further comprises:
forming a first outer surface of the resin spaced apart from a surface of the die by a first dimension directed in a first direction;
forming a second outer surface of the resin spaced apart from the surface of the die by a second dimension in the first direction, the second dimension being less than the first dimension; and
forming a third outer surface transverse to the first and second outer surfaces extending from the first outer surface to the second outer surface.

28. The method of claim 23, further comprising coupling a conductive wire to a lead portion of the leadframe and to a second contact pad at a peripheral region of the die that extends around the central region of the die.

29. The method of claim 23, further comprising:
forming a second opening in the resin with the laser extending to a surface of a second contact pad of the die spaced apart from the first contact pad and extending to a lead portion of the leadframe;
forming a second conductive layer to line the second opening; and
covering the second conductive layer with the conductive material by forming the conductive material on the second conductive layer.

30. The method of claim 29, wherein:
covering the first conductive layer with the conductive material by forming the conductive material on the first conductive layer includes forming the conductive material to be exposed from a surface of the resin doped with the additive conductive material; and
covering the second conductive layer with the conductive material by forming the conductive material on the second conductive layer includes forming the conductive material to be exposed from the surface of the resin doped with the additive conductive material.

31. The method of claim 23, further comprising bending a lead portion of the leadframe to be curved.
